(19) United States
(12) Patent Application Publication
(10) Pub. No.: US 2026/0144098 A1
(43) Pub. Date: May 21, 2026

(54) PACKAGE SUBSTRATE AND MANUFACTURING METHOD THEREOF

(71) Applicant: AaltoSemi Inc., Nanjing City (CN)

(72) Inventors: Yin-Ju CHEN, Nanjing City (CN); Min-Yao CHEN, Nanjing City (CN); Yang-Li WU, Nanjing City (CN); Andrew C. CHANG, Nanjing City (CN)

(73) Assignee: AaltoSemi Inc., Nanjing City (CN)

(21) Appl. No.: 19/290,544

(22) Filed: Aug. 5, 2025

(30) Foreign Application Priority Data
Nov. 19, 2024 (CN) 202411654362.2

(51) Int. Cl. H01L 23/498; H01L 21/48

(52) U.S. Cl. CPC H10W 70/635; H10W 70/095; H10W 70/65

(57) ABSTRACT

Provided are a package substrate and a manufacturing method of the package substrate. A circuit structure is formed on one side of a core board body having a core layer, and the other side of the core board body is used as a ball-placing side, effectively reducing the number of layers in the package substrate. Therefore, the overall thickness of the package substrate is reduced.

### CROSS-REFERENCE TO RELATED APPLICATIONS

This application claims priority to Chinese Application Serial No. 202411654362.2, filed on Nov. 19, 2024. The entirety of the above-mentioned patent application is hereby incorporated by reference herein and made a part of this specification.

### BACKGROUND

### 1. Technical Field

The present disclosure relates to a semiconductor packaging technology, and in particular, to a package substrate and a manufacturing method thereof that can meet thinning requirements.

### 2. Description of Related Art

With the vigorous development of the electronics industry, electronic products are becoming thinner, lighter, and smaller in shape, and their functions are being developed towards high performance, high functionality, and high speed. Therefore, in order to meet the requirements of high integration and miniaturization of semiconductor devices, a package substrate with a thinner design, low warpage, and high-density wiring is often used in the packaging process.

However, in the conventional method of manufacturing package substrates, existing equipment carries a risk of damage due to substrate thickness constraints, which limits its ability to process thinner substrates. Therefore, when producing package substrates designed for thinning and low warpage, specialized equipment with unique specifications must be implemented, making it difficult to reduce production costs.

Therefore, how to overcome the aforementioned problems of the prior art has become an urgent issue that needs to be solved.

### SUMMARY

In view of the aforementioned shortcomings of the prior art, the present disclosure provides a package substrate, which comprises: a core board body, comprising: a core layer having a first side, a second side opposite to the first side, and at least one through-hole connecting the first side and the second side; at least one conductive pillar formed in the at least one through-hole; two wiring layers respectively formed on the first side and the second side of the core layer, wherein the two wiring layers are electrically connected to the conductive pillar; and a plurality of ball pads arranged on the wiring layer on the first side of the core layer; an insulating layer formed on the first side of the core layer, wherein the wiring layer on the first side of the core layer is embedded in the insulating layer; and a circuit structure formed on the second side of the core layer and electrically connected to the wiring layer on the second side of the core layer.

The present disclosure also provides a method of manufacturing a package substrate, and the method comprises: providing a plurality of core board bodies, wherein each of the core board bodies comprises: a core layer having a first side, a second side opposite to the first side, and at least one through-hole connecting the first side and the second side; at least one conductive pillar formed in the at least one through-hole; two wiring layers respectively formed on the first side and the second side of the core layer, and respectively electrically connected to the conductive pillar; and a plurality of ball pads arranged on the wiring layer on the first side of the core layer; bonding the core board body to each of opposite sides of a carrier via an insulating layer, wherein the wiring layer formed on the first side of the core layer is embedded in the insulating layer; forming a circuit structure on the second side of the core layer, and electrically connecting the circuit structure to the wiring layer on the second side of the core layer; and removing the carrier to expose the insulating layer.

In the aforementioned package substrate and method, the conductive pillar is hollow, and a plugging material is filled into the through-hole.

In the aforementioned package substrate, the present disclosure further comprises: a plurality of openings formed on the insulating layer and exposing the plurality of ball pads on the first side of the core layer. Correspondingly, in a specific embodiment of the aforementioned method of manufacturing the package substrate, the present disclosure further comprises: after removing the carrier, forming a plurality of openings on the insulating layer to expose the plurality of ball pads on the first side of the core layer, wherein the insulating layer is used as a solder mask.

In the aforementioned package substrate and method, the present disclosure further comprises: forming a solder mask layer on the circuit structure.

In the aforementioned package substrate, the insulating layer is formed with a plurality of openings penetrating through the insulating layer and exposing the plurality of ball pads on the first side of the core layer, and a solder mask layer is formed on the insulating layer. Correspondingly, in a specific embodiment of the aforementioned method of manufacturing the package substrate, the present disclosure further comprises: after removing the carrier, forming a plurality of openings penetrating through the insulating layer to expose the plurality of ball pads on the first side of the core layer; and forming a solder mask layer on the insulating layer, wherein the plurality of ball pads are exposed from the insulating layer and the solder mask layer.

As can be seen from the above, in the package substrate and the manufacturing method thereof according to the present disclosure, the first side of the core layer is used as the ball-placing side to reduce the number of layers of the package substrate. Therefore, compared with the prior art, the overall thickness of the package substrate is reduced.

Moreover, with the ball grid array (BGA) design on the first side of the core layer, the core board body features standard ball-placing pad size, spacing, and conductive pillar diameter. Therefore, regardless of the wiring design of the circuit structure, the substrate with the through-holes can be fabricated into the core board body for use in a BGA-spec package substrate, thereby saving processing time.

Furthermore, the present disclosure can effectively prevent the problem of warping from occurring to the package substrate by designing the core layer with high hardness.

In addition, the present disclosure uses the first side of the core layer as the ball-placing side, so that solder balls can be placed thereon to directly contact the circuit board, thereby shortening the conductive path and reducing signal loss.

### BRIEF DESCRIPTION OF THE DRAWINGS

FIG. 1A to FIG. 1F-1 are schematic cross-sectional views illustrating a method of manufacturing a package substrate according to an exemplary first embodiment of the present disclosure.

FIG. 1F-2 is a schematic cross-sectional view of the package substrate having a bonding layer according to the exemplary first embodiment of the present disclosure.

FIG. 2A to FIG. 2E-1 are schematic cross-sectional views illustrating a method of manufacturing a package substrate according to an exemplary second embodiment of the present disclosure.

FIG. 2E-2 is a schematic cross-sectional view of the package substrate having a bonding layer according to the exemplary second embodiment of the present disclosure.

### DETAILED DESCRIPTION

The following describes the implementation of the present disclosure through specific exemplary embodiments, so that a person who is familiar with the art can easily understand the other advantages and effects of the present disclosure by the content disclosed in this specification.

It should be noted that the structures, proportions, sizes, etc. illustrated in the drawings attached to this specification are exemplary and only used to describe the package substrate and methods related thereto as disclosed in the specification to facilitate understanding and reading by those who are familiar with the art. These descriptions are exemplary and are not to be considered to limit the conditions under which the present disclosure can be implemented. Any modification of the structure, change in the proportion relationship, or adjustment of the size should be considered to fall within the scope of the present disclosure without affecting the effects and purposes that can be achieved by the present disclosure. Meanwhile, terms such as “above,” “on,” “first,” “second,” “a,” “one,” etc. cited in the specification are only for the convenience of clarity in description and are not intended to limit the scope of the present disclosure. Changes or adjustments in their relative relationships should be regarded as the scope of the present disclosure without substantially changing the technical content.

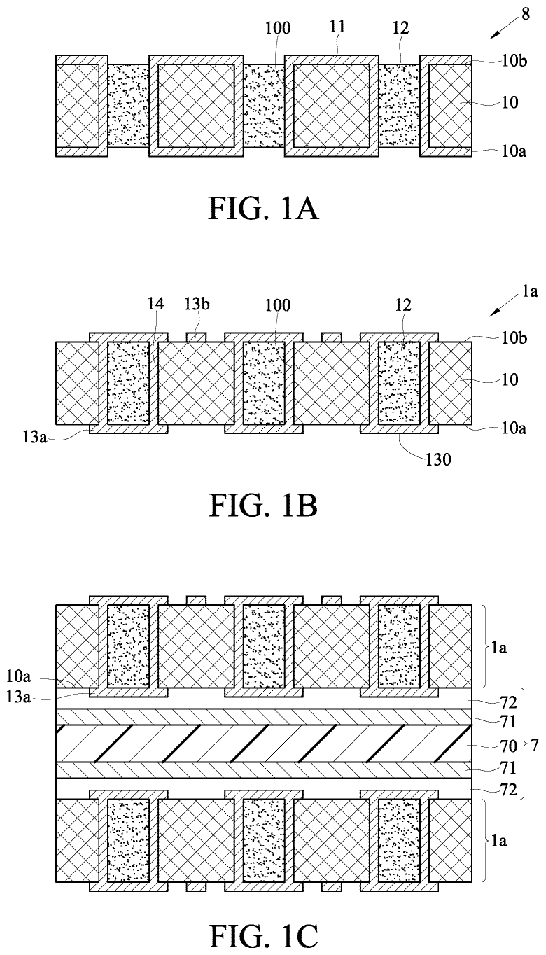

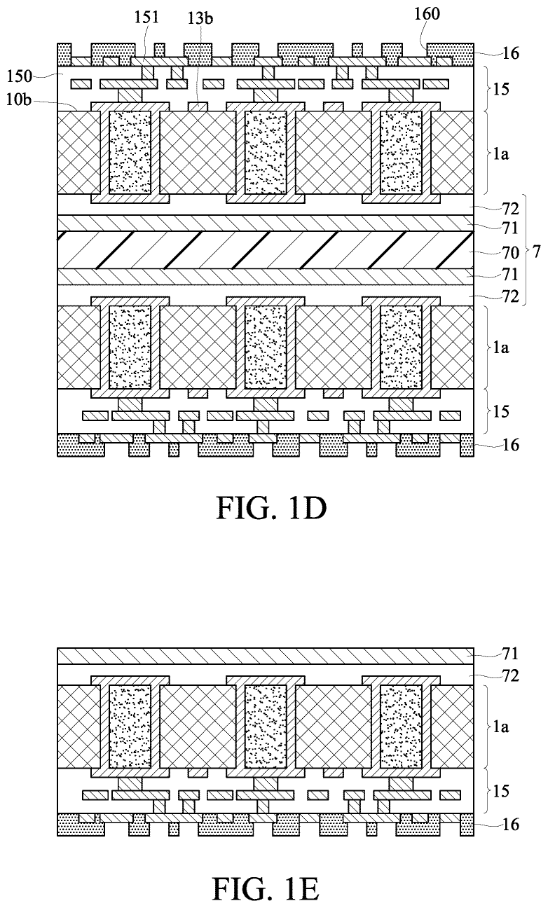

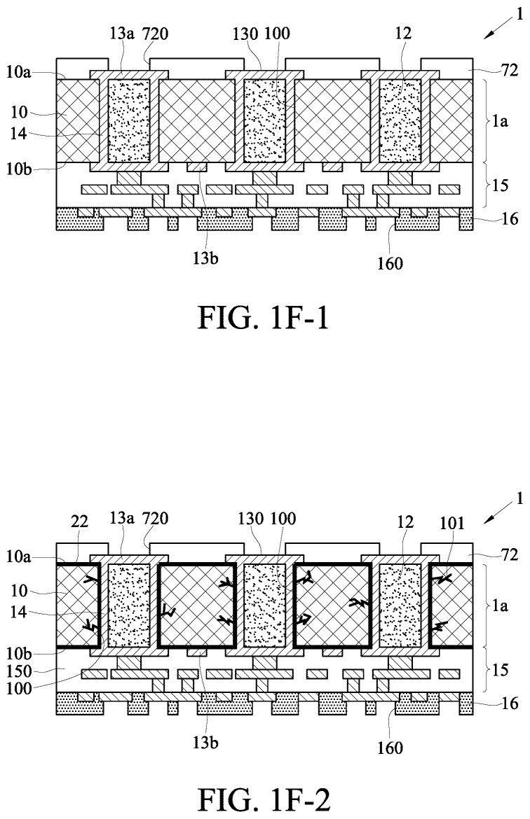

FIG. 1A to FIG. 1F-1 are schematic cross-sectional views illustrating a method of manufacturing a package substrate 1 according to an exemplary first embodiment of the present disclosure.

As shown in FIG. 1A, a substrate 8 is provided and comprises a core layer 10 having a plurality of through-holes 100, and a conductive layer 11 formed on the core layer 10 and within the through-holes 100.

In one embodiment, the core layer 10 has a first side 10a and a second side 10b opposite to the first side 10a. The core layer 10 is made of a high-hardness dielectric material, such as glass, ceramic, silicon carbide (SiC), AlO₂, or a high-rigidity composite material with a modulus ranging from 50 Gpa to 100 Gpa. For example, the plurality of cylindrical through-holes 100 are formed by laser drilling through the first side 10a and the second side 10b of the core layer 10.

Moreover, the conductive layer 11 is formed on the wall surfaces of the through-holes 100. For example, the conductive layer 11 can be used as a barrier layer and a seed layer.

Furthermore, a plugging material 12 can be filled into the through-holes 100. For example, the plugging material 12 may be an ink material applied via injection, plugging, or coating. Additionally, the ink material primarily consists of epoxy ink composites, which possess physical properties such as a viscosity of 25 Pa·s to 55 Pa·s, a glass transition temperature (Tg) of 145° C. to 180° C., and a Young's modulus of ≥3 GPa. Therefore, by injecting ink (the plugging material 12) to fill the through-holes 100 of the core layer 10, processing and material consumption costs can be reduced.

As shown in FIG. 1B, a patterned wiring process is performed via the conductive layer 11 on the surfaces of the core layer 10, thereby forming a wiring layer 13a and a wiring layer 13b on the first side 10a and the second side 10b of the core layer 10, respectively. Additionally, the conductive layer 11 within the through-holes 100 is used as hollow conductive pillars 14, thereby forming a core board body 1a.

As shown in FIG. 1C, the two core board bodies 1a are respectively bonded to opposite sides of a carrier 7, with each core board body 1a being bonded to the carrier 7 via its first side 10a.

In one embodiment, the carrier 7 is a double-capacity bonding material, such as a copper-clad laminate (CCL). The core board bodies 1a are laminated onto copper foils 71 on both sides of a board body 70 of the carrier 7 via insulating layers 72, and the wiring layer 13a on the first side 10a of each core board body 1a is buried in the respective insulating layer 72. For example, the insulating layer 72 is made of polybenzoxazole (PBO), polyimide (PI), fiberglass-reinforced prepreg (PP), or other dielectric materials.

Therefore, in the manufacturing process of the package substrate 1 in the embodiment, the design of the carrier 7 enables subsequent patterned circuit layer buildup in a symmetrical manner, which helps improve the yield of fine line width/fine line spacing (L/S).

In addition, if a thinner substrate 8 is used, the configuration of the carrier 7 not only facilitates handling and transportation during the manufacturing process but also significantly increases (e.g., doubles) the production yield.

As shown in FIG. 1D, a symmetrical patterned circuit layer build-up operation is performed to form a circuit structure 15 electrically connected to the wiring layer 13b on the second side 10b of each core board body 1a. Subsequently, a solder mask layer 16 is formed on the circuit structure 15.

In one embodiment, the circuit structure 15 comprises at least one dielectric layer 150 formed on the core board body 1a, and at least one circuit layer 151 formed on the dielectric layer 150 and electrically connected to the wiring layer 13b. For example, the circuit structure 15 is manufactured using a build-up process, such as electroplating metal (e.g., copper) or other methods.

Moreover, the dielectric layer 150 is made of Ajinomoto Build-up Film (ABF) or other dielectric materials, while the circuit layer 151 is made of copper and may follow the specifications of a redistribution layer (RDL).

Furthermore, parts of the surface of the circuit layer 151 are exposed from the solder mask layer 16 to be used as electrical contact pads. For example, a plurality of openings 160 are formed on the solder mask layer 16 to expose the circuit layer 151.

In addition, the circuit structure 15 and the core board body 1a together have four wiring layers. The line width/line spacing (L/S) configurations of the three layers, from the outermost circuit layer 151 to the wiring layer 13b on the second side 10b, are sequentially set, for example, as 5/5 μm, 8/10 μm, and 15/15 μm. Meanwhile, the wiring layer 13a on the first side 10a comprises a plurality of ball pads 130. It should be understood that the number of wiring layers in the circuit structure 15 can be adjusted as needed and is not limited to the two layers mentioned above.

As shown in FIG. 1E, the board body 70 of the carrier 7 is removed, leaving the copper foil 71 retained on the insulating layer 72.

In one embodiment, the first side 10a of the core board body 1a is used as the ball-placing side, and the second side 10b of the core board body 1a is used as the layer-adding side or the build-up side. For example, the width of the wiring layer 13a (the ball pad 130) of the first side 10a is greater than, less than, or equal to the width of the through-hole 100.

As shown in FIG. 1F-1, the copper foil 71 is first removed to expose the insulating layer 72. Then, a plurality of openings 720 are formed on the insulating layer 72 to expose the wiring layer 13a (the ball pads 130).

In one embodiment, the insulating layer 72 can be used as a solder mask, and thus there is no need to form another solder mask layer.

Therefore, in the package substrate 1 and the manufacturing method thereof of the embodiment, the first side 10a of the core layer 10 is used as the ball-placing side to reduce the number of layers of the package substrate 1. Therefore, compared with the prior art, the overall thickness of the package substrate 1 is reduced.

Moreover, with the ball grid array (BGA) design on the first side 10a of the core layer 10, the core board body 1a features standard ball-placing pad size, spacing, and conductive pillar 14 diameter. Therefore, regardless of the wiring design of the circuit structure 15, the substrate 8 with the through-holes 100 can be fabricated into the core board body 1a for use in the BGA-spec package substrate 1, thereby saving processing time.

Furthermore, by designing the core layer 10 with high hardness, the problem of warping can be effectively prevented from occurring to the package substrate 1.

In addition, by using the first side 10a of the core layer 10 as the ball-placing side, solder balls (not shown) can be placed thereon to directly contact the circuit board, thereby shortening the conductive path and reducing signal loss.

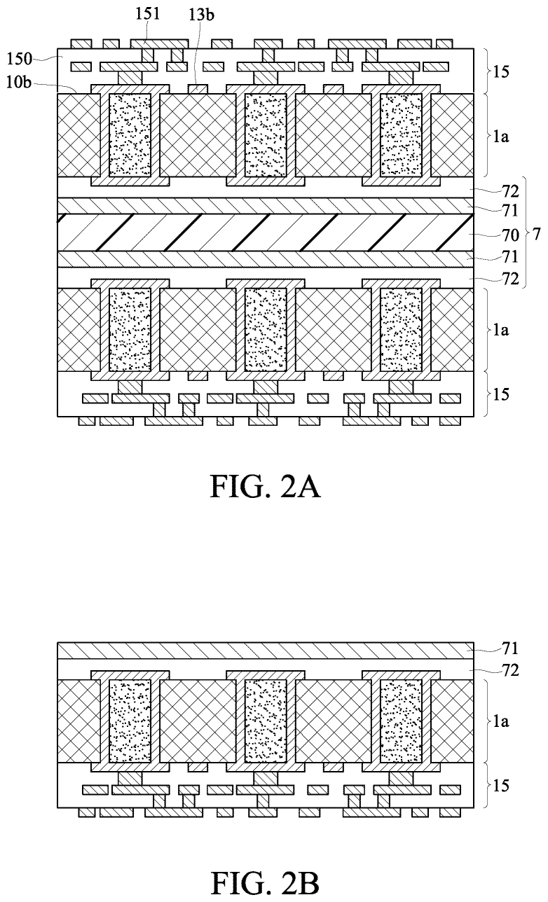

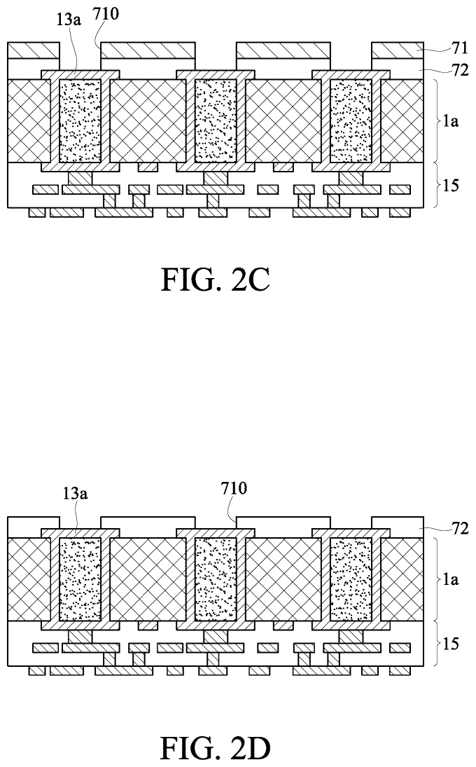

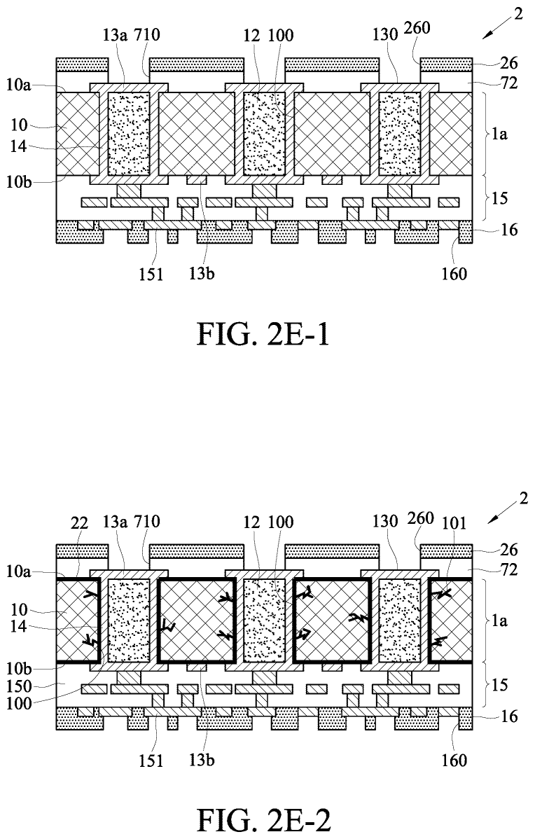

FIG. 2A to FIG. 2E-1 are schematic cross-sectional views illustrating a method of manufacturing a package substrate 2 according to an exemplary second embodiment of the present disclosure. The difference between the second embodiment and the first embodiment lies in the arrangement of the solder mask layer, so the similarities will not be described in detail below.

As shown in FIG. 2A, in the manufacturing process shown in FIG. 1D, only the circuit structure 15 is manufactured, and the solder mask layer 16 is not formed on the circuit structure 15.

As shown in FIG. 2B, the board body 70 of the carrier 7 is removed, leaving the copper foil 71 retained on the insulating layer 72.

As shown in FIG. 2C, a plurality of openings 710 are formed on the copper foil 71, penetrating through the insulating layer 72 to expose the wiring layer 13a (the ball pads 130) on the first side 10a of the core layer 10.

As shown in FIG. 2D, the copper foil 71 is removed to expose the insulating layer 72.

As shown in FIG. 2E-1, solder mask layers 16, 26 are formed on the circuit structure 15 and the insulating layer 72, respectively.

In one embodiment, parts of the surface of the circuit layer 151 are exposed from the solder mask layer 16, and the wiring layer 13a (the ball pads 130) is exposed from the solder mask layer 26. For example, a plurality of openings 260 are formed on the solder mask layer 26 to expose the wiring layer 13a (the ball pads 130), and the openings 260 correspond to the openings 710 of the insulating layer 72 shown in FIG. 2C. Further, a plurality of openings 160 are formed on the solder mask layer 16 to expose the circuit layer 151, and the exposed surfaces of the circuit layer 151 are served as electrical contact pads.

Therefore, in the package substrate 2 and the manufacturing method thereof of the embodiment, the first side 10a of the core layer 10 is used as the ball-placing side to reduce the number of layers of the package substrate 2. Therefore, compared with the prior art, the overall thickness of the package substrate 2 is reduced.

Moreover, with the ball grid array design on the first side 10a of the core layer 10, the core board body 1a features standard ball-placing pad size, spacing, and conductive pillar 14 diameter. Therefore, regardless of the wiring design of the circuit structure 15, the substrate 8 with the through-holes 100 can be fabricated into the core board body 1a for use in the BGA-spec package substrate 2, thereby saving processing time.

Furthermore, by designing the core layer 10 with high hardness, the problem of warping can be effectively prevented from occurring to the package substrate 2.

In addition, by using the first side 10a of the core layer 10 as the ball-placing side, solder balls (not shown) can be placed thereon to directly contact the circuit board, thereby shortening the conductive path and reducing signal loss.

In some specific implementations, based on the two aforementioned embodiments, a bonding layer 22 may be formed as needed to enhance adhesion on the surface of the core layer 10 and the wall surfaces of the through-holes 100, and then the plugging material 12 is bonded by the bonding layer 22. Alternatively, the bonding layer 22 can be formed before the conductive layer 11 is formed on the core layer 10. Therefore, the bonding layer 22 is located between the core layer 10 and the conductive pillar 14, and/or between the core layer 10 and the wiring layers 13a, 13b, and/or between the core layer 10 and the insulating layer 72 and the dielectric layer 150.

Moreover, the bonding layer 22 can be an organic coating formed by a chemical process, for example, by depositing an organic polymer such as polyphenylene oxide (PPO), polyamide (PA), or poly-dimethylbenzene (PD). Further, a thinner organic coating can be formed by chemical vapor deposition (CVD) to enhance insulation, corrosion resistance, and protection of the surface of the high-rigidity core layer 10. The thickness of the bonding layer 22 is, for example, 1 nm to 100 μm, and the organic coating can infiltrate into cracks to limit the expansion of the cracks. As shown in FIG. 1F-2 and FIG. 2E-2, the bonding layer 22 of the organic coating infiltrates into cracks 101 of the glass-based core layer 10, reducing the dielectric constant (Dk) of the core layer 10 to 2.5 to 5 (at 1 GHz), including Dk values such as 2.5, 2.65, 2.7, 2.8, 2.9, 3.0, 3.2, 3.5, 3.7, 4.0, 4.2, 4.5, 4.7, and 5.0 (at 1 GHz).

On the other hand, the bonding layer 22 can also be an inorganic coating formed via a physical process to generate Van der Waals forces. For example, silica sand with a diameter of 20 microns to 50 microns and a roughness (Ra) of 1 microns to 200 microns can be used for sandblasting. This sandblasting process not only removes oxides and impurities on the core layer 10 but also increases the surface area of the core layer 10, thereby enhancing the adhesion between the insulating layer 72 and the core layer 10 when the insulating layer 72 is formed on the high-hardness core layer 10. Therefore, in one embodiment, the bonding layer 22 is formed using silica sand with a diameter of 20 microns to 50 microns and a roughness (Ra) of 1 microns to 200 microns.

The present disclosure also provides a package substrate 1, 2, which comprises: a core board body 1a, an insulating layer 72, and a circuit structure 15.

The core board body 1a comprises: a core layer 10 having a first side 10a, a second side 10 b opposite to the first side 10 a, and at least one through-hole 100 connecting the first side 10a and the second side 10b; at least one conductive pillar 14 formed in the through-hole 100; a wiring layer 13 a and a wiring layer 13b respectively formed on the first side 10a and the second side 10b of the core layer 10 and electrically connected to the conductive pillar 14; and a plurality of ball pads 130 arranged on the wiring layer 13a of the first side 10a.

The insulating layer 72 is formed on the first side 10a of the core layer 10, and the wiring layer 13a on the first side 10a of the core layer 10 is buried in the insulating layer 72.

The circuit structure 15 is formed on the second side 10b of the core layer 10 and is electrically connected to the wiring layer 13b on the second side 10b of the core layer 10.

In one embodiment, the conductive pillar 14 is hollow, and the through-hole 100 is filled with a plugging material 12.

In one embodiment, the insulating layer 72 is used as a solder mask, and the ball pads 130 are exposed from the insulating layer 72.

In one embodiment, the package substrate 1, 2 further comprises a solder mask layer 16 formed on the circuit structure 15.

In one embodiment, the package substrate 2 further comprises a solder mask layer 26 formed on the insulating layer 72, wherein the ball pads 130 are exposed from the insulating layer 72 and the solder mask layer 26.

In summary, in the package substrate and the manufacturing method thereof according to the present disclosure, the first side of the core layer is used as the ball-placing side to reduce the number of layers of the package substrate, so that the overall thickness of the package substrate is reduced.

Furthermore, with the ball grid array design on the first side of the core layer, the core board body features standard ball-placing pad size, spacing, and conductive pillar diameter. Therefore, regardless of the wiring design of the circuit structure, the substrate with the through-holes can be fabricated into the core board body for use in a BGA-spec package substrate, thereby saving processing time.

In addition, the present disclosure can effectively prevent the problem of warping from occurring to the package substrate by designing the core layer with high hardness.

Moreover, the present disclosure uses the first side of the core layer as the ball-placing side, so that solder balls can be placed thereon to directly contact the circuit board, thereby shortening the conductive path and reducing signal loss.

The aforementioned embodiments are provided for illustrating the principles of the present disclosure and its technical effect, which should not be used to limit the present disclosure. The aforementioned embodiments can be modified by one of ordinary skill in the art without departing from the spirit and scope of the present disclosure. Therefore, the claimed scope of the present disclosure should be defined by the following claims.

What is claimed is:

1. A package substrate, comprising:
a core board body, comprising:
a core layer having a first side, a second side opposite to the first side, and at least one through-hole connecting the first side and the second side;
at least one conductive pillar formed in the at least one through-hole;
two wiring layers respectively formed on the first side and the second side of the core layer, wherein the two wiring layers are electrically connected to the conductive pillar; and
a plurality of ball pads arranged on the wiring layer on the first side of the core layer;
an insulating layer formed on the first side of the core layer, wherein the wiring layer on the first side of the core layer is embedded in the insulating layer; and
a circuit structure formed on the second side of the core layer and electrically connected to the wiring layer on the second side of the core layer.

2. The package substrate of claim 1, wherein the conductive pillar is hollow, and a plugging material is filled into the through-hole.

3. The package substrate of claim 1, further comprising a plurality of openings formed in the insulating layer for exposing the plurality of ball pads on the first side of the core layer, wherein the insulating layer serves as a solder mask.

4. The package substrate of claim 1, further comprising a solder mask layer formed on the circuit structure.

5. The package substrate of claim 1, wherein the insulating layer is formed with a plurality of openings penetrating through the insulating layer and exposing the plurality of ball pads on the first side of the core layer, a solder mask layer is formed on the insulating layer, and the plurality of ball pads are exposed from the insulating layer and the solder mask layer.

6. A method of manufacturing a package substrate, comprising:
providing a plurality of core board bodies, wherein each of the core board bodies comprises: a core layer having a first side, a second side opposite to the first side, and at least one through-hole connecting the first side and the second side; at least one conductive pillar formed in the at least one through-hole; two wiring layers respectively formed on the first side and the second side of the core layer, and respectively electrically connected to the conductive pillar; and a plurality of ball pads arranged on the wiring layer on the first side of the core layer;
bonding the core board body to each of opposite sides of a carrier via an insulating layer, wherein the wiring layer formed on the first side of the core layer is embedded in the insulating layer;
forming a circuit structure on the second side of the core layer, and electrically connecting the circuit structure to the wiring layer on the second side of the core layer; and
removing the carrier to expose the insulating layer.

7. The method of claim 6, wherein the conductive pillar is hollow, and a plugging material is filled into the through-hole.

8. The method of claim 6, further comprising, after removing the carrier, forming a plurality of openings in the insulating layer to expose the plurality of ball pads on the first side of the core layer, wherein the insulating layer serves as a solder mask.

9. The method of claim 6, further comprising forming a solder mask layer on the circuit structure.

10. The method of claim 6, further comprising, after removing the carrier, forming a plurality of openings penetrating through the insulating layer to expose the plurality of ball pads on the first side of the core layer; and forming a solder mask layer on the insulating layer, wherein the plurality of ball pads are exposed from the insulating layer and the solder mask layer.
